(19) United States
(12) Patent Application Publication
(10) Pub. No.: US 2026/0090223 A1
(43) Pub. Date: Mar. 26, 2026

(54) DISPLAY DEVICE AND ELECTRONIC DEVICE INCLUDING THE SAME

(71) Applicant: Samsung Display Co., Ltd., Yongin-si (KR)

(72) Inventors: Kiyong Kim, Yongin-si (KR); Heeju Woo, Yongin-si (KR); Cholong Won, Yongin-si (KR); Hyungbin Cho, Yongin-si (KR); Kyungbin Choi, Yongin-si (KR)

(21) Appl. No.: 19/088,659

(22) Filed: Mar. 24, 2025

(30) Foreign Application Priority Data
Sep. 26, 2024 (KR) 10-2024-0131092

(51) Int. Cl. H10K 59/131; G06F 3/044; H10K 59/40; H10K 59/80

(52) U.S. Cl. CPC H10K 59/131; G06F 3/0446; H10K 59/40; H10K 59/871

(57) ABSTRACT

An electronic device includes a display panel including: a substrate including a display area and a pad area; a thin film transistor in the display area and comprising a semiconductor layer, a gate layer on the semiconductor layer, and a first conductive layer electrically connected to the semiconductor layer; a second conductive layer on the thin film transistor and electrically connected to the first conductive layer; a pixel electrode on the second conductive layer and electrically connected to the second conductive layer; an input sensing layer on the pixel electrode and comprising a touch conductive layer and an organic insulating layer; a support pad layer in the pad area and including a same material as the pixel electrode; a polymer pad on the support pad layer; and an upper pad layer on the polymer pad and including a same material as the touch conductive layer.

### CROSS-REFERENCE TO RELATED APPLICATION

The present application claims priority to and the benefit of Korean Patent Application No. 10-2024-0131092, filed on Sep. 26, 2024, in the Korean Intellectual Property Office, the entire disclosure of which is incorporated herein by reference.

### BACKGROUND

### 1. Field

Aspects of some embodiments relate to a display device and an electronic device including the same.

### 2. Description of the Related Art

Mobility-based electronic devices are in wide use. As mobile electronic devices, not only compact electronic devices such as mobile phones but also tablet PCs have recently become widely used.

To support various functions, such mobile electronic devices include a display device to provide users with visual information such as images or videos. Recently, as other components for driving a display device are miniaturized, the proportion occupied by display devices in electronic devices is gradually increasing, and structures to enable bending of a display device from a flat state to have a certain angle are under development.

The above information disclosed in this Background section is only for enhancement of understanding of the background and therefore the information discussed in this Background section does not necessarily constitute prior art.

### SUMMARY

Aspects of some embodiments include a display device in which a pad and a signal pad contact each other accurately at a desired position.

Furthermore, one or more embodiments include a display panel having a pad with a relatively reduced size.

However, such characteristics are examples, and the characteristics of embodiments according to the present disclosure are not limited thereto.

Additional aspects will be set forth in part in the description which follows and, in part, will be apparent from the description, or may be learned by practice of the presented embodiments of the disclosure.

According to some embodiments, a display device includes a display panel including a substrate including a display area and a pad area, a display portion arranged in the display area of the substrate, and a pad arranged in the pad area of the substrate, and a connection circuit board including a signal pad electrically connected to the pad, wherein the display portion may include a thin film transistor on the substrate and including a semiconductor layer, a gate layer on the semiconductor layer, and a first conductive layer electrically connected to the semiconductor layer, a second conductive layer on the thin film transistor and electrically connected to the first conductive layer, a pixel electrode on the second conductive layer to be electrically connected to the second conductive layer, and an input sensing layer on the pixel electrode and including a touch conductive layer and an organic insulating layer, and wherein the pad may include a support pad layer on the substrate and including the same material as the pixel electrode, a polymer pad on the support pad layer, and an upper pad layer on the polymer pad and including the same material as the touch conductive layer.

According to some embodiments, in a plan view, the polymer pad may overlap the support pad layer, and the support pad layer may support the polymer pad.

According to some embodiments, the upper pad layer may cover the polymer pad.

According to some embodiments, the pad may further include a first conductive pad layer that is provided between the substrate and the support pad layer and may include the same material as the gate layer.

According to some embodiments, the pad may further include a second conductive pad layer that is provided between the first conductive pad layer and the support pad layer, contacts the first conductive pad layer, and may include the same material as the first conductive layer.

According to some embodiments, the pad may further include a third conductive pad layer that is provided between the second conductive pad layer and the support pad layer, contacts the second conductive pad layer, and may include the same material as the second conductive layer.

According to some embodiments, the pad may further include a third conductive pad layer that is provided between the first conductive pad layer and the support pad layer, contacts the first conductive pad layer, and may include the same material as the second conductive layer.

According to some embodiments, the polymer pad and the support pad layer may include a plurality of polymer pads and a plurality of support pad layers, respectively, and, in a plan view, each of the plurality of support pad layers may overlap a corresponding one of the plurality of polymer pads.

According to some embodiments, the plurality of support pad layers may be spaced apart from each other.

According to some embodiments, the signal pad may contact the upper pad layer.

According to one or more embodiments, an electronic device includes a display panel, and a connection circuit board electrically connected to the display panel, wherein the display panel may include a substrate including a display area and a pad area, a thin film transistor arranged in the display area of the substrate and including a semiconductor layer, a gate layer on the semiconductor layer, and a first conductive layer electrically connected to the semiconductor layer, a second conductive layer on the thin film transistor and electrically connected to the first conductive layer, a pixel electrode on the second conductive layer to be electrically connected to the second conductive layer, an input sensing layer on the pixel electrode and including a touch conductive layer and an organic insulating layer, a support pad layer in the pad area of the substrate and including the same material as the pixel electrode, a polymer pad on the support pad layer, and an upper pad layer on the polymer pad and including the same material as the touch conductive layer.

According to some embodiments, the connection circuit board may include a signal pad electrically connected to the upper pad layer.

According to some embodiments, in a plan view, the polymer pad may overlap the support pad layer, and the support pad layer may support the polymer pad.

According to some embodiments, the upper pad layer may cover the polymer pad.

According to some embodiments, the display panel may further include a first conductive pad layer that is provided between the substrate and the support pad layer and may include the same material as the gate layer.

According to some embodiments, the display panel may further include a second conductive pad layer that is provided between the first conductive pad layer and the support pad layer, contacts the first conductive pad layer, and may include the same material as the first conductive layer.

According to some embodiments, the display panel may further include a third conductive pad layer that is provided between the second conductive pad layer and the support pad layer, contacts the second conductive pad layer, and may include the same material as the second conductive layer.

According to some embodiments, the display panel may further include a third conductive pad layer that is provided between the first conductive pad layer and the support pad layer, contacts the first conductive pad layer, and may include the same material as the second conductive layer.

According to some embodiments, the polymer pad and the support pad layer may include a plurality of polymer pads and a plurality of support pad layers, respectively, and, in a plan view, each of the plurality of support pad layers may overlap a corresponding one of the plurality of polymer pads.

According to some embodiments, the plurality of support pad layers may be spaced apart from each other.

Other aspects, features, and characteristics than those described above will become apparent from the following drawings, claims, and detailed description of the disclosure

### BRIEF DESCRIPTION OF THE DRAWINGS

The above and other aspects, features, and characteristics of certain embodiments of the disclosure will be more apparent from the following description taken in conjunction with the accompanying drawings, in which:

FIG. 1 is a schematic plan view of a display device according to some embodiments;

FIG. 2 is a schematic cross-sectional view of a portion of a display panel according to some embodiments;

FIG. 3 is a schematic plan view of a portion of an input sensing layer according to some embodiments;

FIG. 4 is a schematic plan view of a pad according to some embodiments;

FIG. 5 is a schematic cross-sectional view of the pad of FIG. 4 taken along the line A-A′ shown in FIG. 4, according to some embodiments;

FIG. 6 is a schematic cross-sectional view of the pad of FIG. 4 taken along the line B-B′ shown in FIG. 4, according to some embodiments;

FIG. 7 is a schematic cross-sectional view of a pad and a signal pad (SPD), according to some embodiments;

FIG. 8 is a schematic plan view of a pad according to some embodiments;

FIG. 9 is a schematic cross-sectional view of the pad of FIG. 4 taken along the line A-A′ shown in FIG. 4, according to some embodiments;

FIG. 10 is a schematic cross-sectional view of the pad of FIG. 4 taken along the line A-A′ shown in FIG. 4, according to some embodiments;

FIG. 11 is a schematic cross-sectional view of the pad of FIG. 4 taken along the line A-A′ shown in FIG. 4, according to some embodiments;

FIG. 12 is a schematic cross-sectional view of the pad of FIG. 4 taken along the line A-A′ shown in FIG. 4, according to some embodiments; and

FIG. 13 is a schematic cross-sectional view of the pad of FIG. 4 taken along the line A-A′ shown in FIG. 4, according to some embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Various modifications may be applied to the present embodiments, and particular embodiments will be illustrated in the drawings and described in the detailed description section. The effect and features of the present embodiments, and a method to achieve the same, will be clearer referring to the detailed descriptions below with the drawings. However, the present embodiments may be implemented in various forms, not by being limited to the embodiments presented below.

Hereinafter, embodiments will be described in detail with reference to the accompanying drawings, and in the description with reference to the drawings, the same or corresponding constituents are indicated by the same reference numerals and some redundant descriptions thereof may be omitted.

In the following embodiments, it will be understood that although the terms first, second, etc. may be used herein to describe various elements, these elements should not be limited by these terms. These elements are only used to distinguish one element from another.

In the following embodiments, as used herein, the singular forms “a,” “an,” and “the” are intended to include the plural forms as well, unless the context clearly indicates otherwise.

In the following embodiments, it will be further understood that the terms “comprises” and/or “comprising” used herein specify the presence of stated features or elements, but do not preclude the presence or addition of one or more other features or components.

In the following embodiments, it will be understood that when an element, such as a layer, a film, a region, or a plate, is referred to as being “on” another element, the element can be directly on the other element or intervening elements may be present thereon.

Sizes of elements in the drawings may be exaggerated for convenience of explanation. For example, since sizes and thicknesses of elements in the drawings are arbitrarily illustrated for convenience of explanation, the following embodiments are not limited thereto.

In the following embodiments, the x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

When a certain embodiment may be implemented differently, a specific process order may be performed differently from the described order. For example, two consecutively described processes may be performed substantially at the same time or performed in an order opposite to the described order.

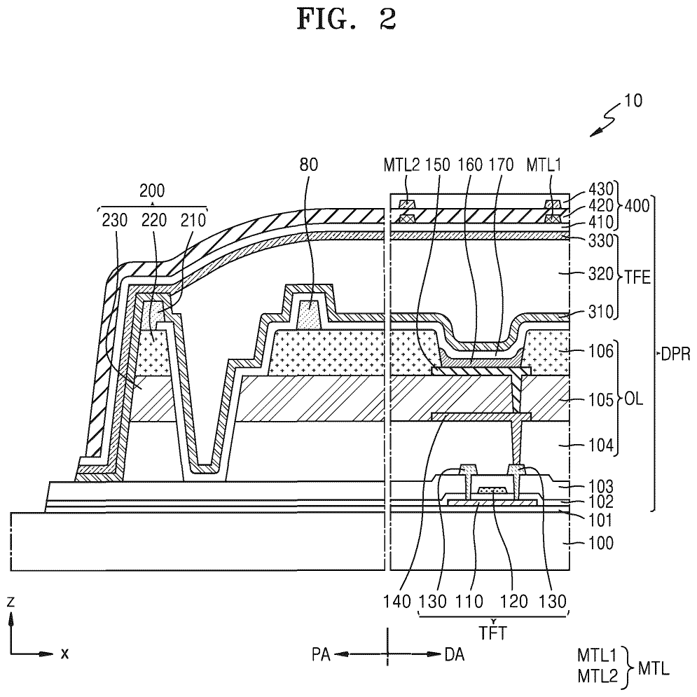

In the specification, an expression “in a plan view” means a plane viewed from a direction perpendicular to a substrate 100 (see FIG. 2). In other words, an expression “in a plan view, A and B apart from each other” means that, when viewed from a direction perpendicular to the substrate 100 (see FIG. 2), A and B are apart from each other.

In the specification, an expression “in a cross-section” means a plane cut in the direction perpendicular to the substrate 100 (see FIG. 2). In other words, an expression “in a plan view, A and B apart from each other” means that A and B are apart from each other in a plane viewed in a direction perpendicular to the substrate 100 (see FIG. 2).

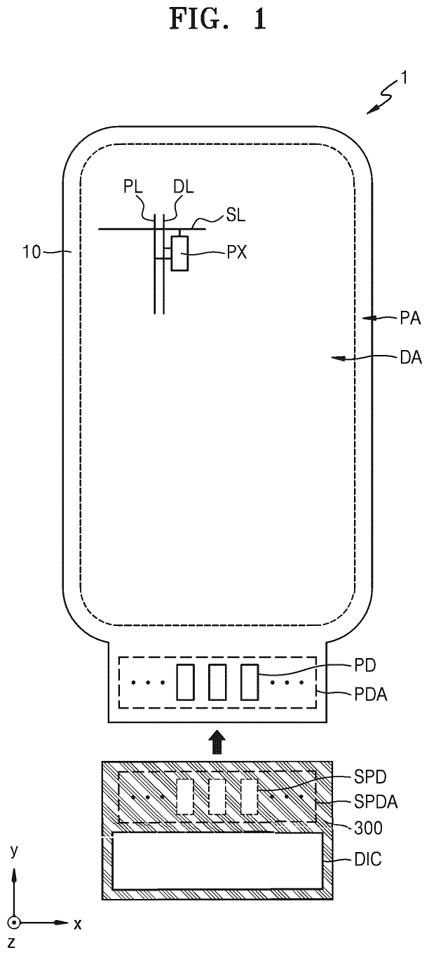

FIG. 1 is a schematic plan view of a display device 1 according to some embodiments.

Referring to FIG. 1, the display device 1 may include a display panel 10 and a connection circuit board 300.

The display device 1 may be an electronic device including the display panel 10. The electronic device may include display devices for vehicles, including a cluster, a center information display (CID), and/or a passenger display, wearable electronic devices wearable on any part of the user's body, electronic devices for medical use, robots, electronic devices for advertisement or display, and/or electronic devices for educational use.

The display panel 10 includes a display area DA and a peripheral area PA outside the display area DA. The display area DA is a portion for displaying images, and a plurality of pixels PX may be arranged in the display area DA. In a plan view, the display area DA may have various shapes, for example, a circular shape, an oval shape, a polygonal shape, a specific figure shape, etc. In FIG. 1, the display area DA is illustrated as having an approximately rectangular shape with round corners.

The peripheral area PA may be arranged outside (e.g., in a periphery or outside a footprint of) the display area DA. The peripheral area PA is an area that does not display an image, and may mean an area surrounding the display area DA.

Each pixel PX may include a display element such as an organic light-emitting element. Each pixel PX may emit, for example, red, green, or blue light. The pixel PX may be connected to a pixel circuit including a thin film transistor (TFT), a storage capacitor, etc. The pixel circuit may be connected to a scan line SL through which a scan signal is transmitted, a data line DL crossing the scan line SL and through which a data signal is transmitted, a driving voltage line PL through which a driving voltage is supplied, etc. The scan line SL may extend in a first direction (e.g., an x-axis direction). The data line DL and the driving voltage line PL may extend in a second direction (e.g., a y-axis direction). The pixel PX may emit light having a luminance corresponding to an electrical signal from a pixel circuit to which the pixel PX is electrically connected. The display area DA may display a certain image through light emitted from the pixel PX. For reference, the pixel PX may be defined as an emission area that emits light of any one of red, green, and blue. Although FIG. 1 illustrates a single pixel PX, a single data line DL, a single scan line SL, and a single driving voltage line PL, as a person having ordinary skill in the art would appreciate, the display panel 10 may include any suitable number of pixels, data lines, scan lines, and driving voltage lines according to the design and size of the display panel 10.

The peripheral area PA is an area where the pixel PX is not arranged, and may be an area that does not display images. A power supply wire for driving the pixel PX, etc. may be arranged in the peripheral area PA. Furthermore, pads may be arranged in the peripheral area PA, a printed circuit board including a drive circuit portion, an integrated circuit (IC) element such as a driver IC, and the pads described above may be electrically connected to one another in the peripheral area PA.

As the display panel 10 includes the substrate 100 (see FIG. 2 or further) to be described below, it may be said that the substrate 100 to be described below has the display area DA and the peripheral area PA that are described above. In the following description, for convenience, it is described that the substrate 100 or the display panel 10 has the display area DA and the peripheral area PA.

A pad area PDA where the pads PD are arranged may be defined in one side of the peripheral area PA. The pad area PDA may be an area to be electrically connected to the connection circuit board 300. The pads PD may be arranged in the pad area PDA of the substrate 100. For example, the pads PD may be electrically connected to or in direct contact with signal pads SPD arranged on a lower surface of the connection circuit board 300. The pads PD of the pad area PDA may exchange electrical signals with the signal pad SPD. Accordingly, the connection circuit board 300 may be electrically connected to the display panel 10.

A signal pad area SPDA where the signal pads SPD are arranged may be defined on the lower surface of the connection circuit board 300. In the signal pad area SPDA, the signal pads SPD may protrude in a downward direction. Reversely, in the pad area PDA, the pads PD may protrude in an upward direction.

A driving chip DIC may be arranged on the connection circuit board 300. The driving chip DIC may include an integrated circuit that drives the display panel 10. The integrated circuit may be a data driving integrated circuit that generates a data signal, but embodiments according to the present disclosure are not limited thereto. The driving chip DIC may be mounted on the connection circuit board 300.

In the following description, an organic light-emitting display device 1 is described as an example of the display device 1 according to some embodiments, but the display device 1 is not limited thereto. According to some embodiments, the display device 1 may include an inorganic light-emitting display device 1 or an inorganic EL display device 1, a quantum-dot light-emitting display device 1. For example, an emission layer of a display element included in the display device 1 may include an organic material or an inorganic material. Furthermore, the display device 1 may include an emission layer and a quantum-dot layer located on a path of light emitted from the emission layer.

FIG. 2 is a schematic cross-sectional view of a portion of the display panel 10 according to some embodiments.

Referring to FIG. 2, the substrate 100 may include the display area DA and the peripheral area PA outside the display area DA. The substrate 100 may include various materials having flexible or bendable characteristics. For example, the substrate 100 may include glass, metal, or polymer resin. Furthermore, the substrate 100 may include polymer resin, such as polyethersulfone, polyacrylate, polyetherimide, polyethylene naphthalate, polyethylene terephthalate, polyphenylene sulfide, polyarylate, polyimide, polycarbonate, or cellulose acetate propionate. The substrate 100 may also be modified in various ways, such as having a multilayer structure in which two layers each including polymer resin and an inorganic material (a silicon oxide, a silicon nitride, a silicon oxynitride, etc.) provided between the two layers.

A buffer layer 101 may be located on the substrate 100. The buffer layer 101 may prevent or reduce diffusion of impurity ions, prevent or reduce infiltration of moisture or external air, serve as a barrier layer for planarizing a surface, and/or serve as a blocking layer. The buffer layer 101 may include a silicon oxide, a silicon nitride, or a silicon oxynitride. Furthermore, the buffer layer 101 may adjust a heat supply speed during a crystallization process for forming a semiconductor layer 110 so as to uniformly crystallize the semiconductor layer 110.

A thin film transistor TFT may be located on the substrate 100. The thin film transistor TFT may include the semiconductor layer 110, a gate layer 120, and a first conductive layer 130. The semiconductor layer 110 may be located on the buffer layer 101. The semiconductor layer 110 may include polysilicon and include a channel region that is not doped with impurities, and a source region and a drain region that are formed on both sides of the channel region and doped with impurities. The impurities vary depending on a type of the thin film transistor TFT, and N-type impurities or P-type impurities is possible.

A gate insulating film 102 may be located on the semiconductor layer 110. The gate insulating film 102 may be a configuration for securing insulation between the semiconductor layer 110 and the gate layer 120. The gate insulating film 102 may include an inorganic material, such as a silicon oxide, a silicon nitride, a silicon oxynitride, etc., and may be provided between the semiconductor layer 110 and the gate layer 120. Furthermore, the gate insulating film 102 may be formed corresponding to the entire surface of the substrate 100, and may have a structure in which contact holes are formed in a preset portion. As such, an insulating film including an inorganic material may be formed through chemical vapor deposition (CVD) or atomic layer deposition (ALD). This also applied to embodiments described below and modified examples thereof.

The gate layer 120 may be located above the semiconductor layer 110. The gate layer 120 may be located on the gate insulating film 102. The gate layer 120 may be arranged at a position to vertically overlap the semiconductor layer 110, and may include at least one metal of molybdenum (Mo), aluminum (Al), platinum (Pt), palladium (Pd), silver (Ag), magnesium (Mg), gold (Au), nickel (Ni), neodymium (Nd), iridium (Ir), chromium (Cr), nickel (Li), calcium (Ca), titanium (Ti), tungsten (W), and copper (Cu).

An interlayer insulating film 103 may be located on the gate layer 120. The interlayer insulating film 103 may cover the gate layer 120. The interlayer insulating film 103 may include an inorganic material. For example, the interlayer insulating film 103 may include a metal oxide or a metal nitride, and in detail, the inorganic material may include silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZrO₂). In some embodiments, the interlayer insulating film 103 may have a dual structure of SiO_{X}/SiN_{y} or SiN_{X}/SiO_{y}.

The first conductive layer 130 may be located on the interlayer insulating film 103. The first conductive layer 130 may be electrically connected to the semiconductor layer 110. The first conductive layer 130 may serve as an electrode connected to source/drain regions of the semiconductor layer 110 through through-holes included in the interlayer insulating film 103. The first conductive layer 130 may include one or more metals selected from among Al, Pt, Pd, Ag, Mg, Au, Ni, Nd, Ir, Cr, Li, Ca, Mo, Ti, W, and Cu. For example, the first conductive layer 130 may include a Ti layer, an Al layer, and/or a Cu layer.

A first organic insulating layer 104 may be located on the first conductive layer 130. The first organic insulating layer 104 may be an organic insulating layer covering an upper portion of the first conductive layer 130 and having an approximately flat upper surface so as to serve as a planarized film. The first organic insulating layer 104 may include an organic material, such as acryl, benzocyclobutene (BCB) or hexamethyldisiloxane (HMDSO). The first organic insulating layer 104 may be modified in various ways, such as having a single layer or a multilayer.

A second conductive layer 140 may be located on an upper portion of the first organic insulating layer 104. The second conductive layer 140 may be arranged above the thin film transistor TFT, and may be electrically connected to the first conductive layer 130. The second conductive layer 140 may be in contact with the first conductive layer 130 through a through-hole included in the first organic insulating layer 104. The second conductive layer 140 may include one or more metals selected from among Al, Pt, Pd, Ag, Mg, Au, Ni, Nd, Ir, Cr, Li, Ca, Mo, Ti, W, and Cu. For example, the second conductive layer 140 may include a Ti layer, an Al layer, and/or a Cu layer.

A second organic insulating layer 105 may be located on the second conductive layer 140. The second organic insulating layer 105 may be an organic insulating layer covering an upper portion of the second conductive layer 140 and having an approximately flat upper surface so as to serve as a planarized film. The second organic insulating layer 105 may include an organic material, such as acryl, BCB, or HMDSO. The second organic insulating layer 105 may be modified in various ways, such as having a single layer or a multilayer.

Furthermore, according to some embodiments, an additional conductive layer and an additional insulating layer may be provided between the first conductive layer 130 and a pixel electrode 150, and may be applied in various embodiments. In this state, the additional conductive layer may include the same material as the conductive layer described above, and may have the same layer structure. The additional insulating layer may include the same material as the organic insulating layer described above, and may have the same layer structure.

The pixel electrode 150 may be located on the second organic insulating layer 105. The pixel electrode 150 may be located on the second conductive layer 140 to be electrically connected to the second conductive layer 140. The pixel electrode 150 may be in contact with the second conductive layer 140 through a contact hole formed in the second organic insulating layer 105. A display element may be located above the pixel electrode 150. An organic light-emitting diode may be used as the display element. In other words, the organic light-emitting diode may be provided, for example, above the pixel electrode 150. The pixel electrode 150 may include a light-transmissive conductive layer formed of a light-transmissive conductive oxide, such as an indium tin oxide (ITO), In₂O₃, or an indium zinc oxide (IZO), and a reflective layer formed of a metal, such as Al or Ag. For example, the pixel electrode 150 may have a triple layer structure of ITO/Ag/ITO.

A pixel defining layer 106 may be located on the second organic insulating layer 105, and may cover an edge of the pixel electrode 150. In other words, the pixel defining layer 106 may cover the edge of the pixel electrode 150. The pixel defining layer 106 may have an opening portion corresponding to the pixel PX, and the opening portion may be formed to expose at least the center portion of the pixel electrode 150. The pixel defining layer 106 may include an organic material, such as polyimide or HMDSO. Furthermore, a spacer 80 may be located on the pixel defining layer 106.

The first organic insulating layer 104, the second organic insulating layer 105, and the pixel defining layer 106 may be defined as an organic material layer OL.

Although the spacer 80 is illustrated as being located in the peripheral area PA, the spacer 80 may be located in the display area DA. The spacer 80 may prevent or reduce damage to an organic light-emitting diode due to sagging of a mask in a manufacturing process using a mask. The spacer 80 may include an organic insulating material, and may be formed in a single layer or a multilayer.

An intermediate layer 160 and a counter electrode 170 may be located in an opening portion of the pixel defining layer 106. The intermediate layer 160 may include a low molecular weight or polymer material, and when including a low molecular weight material, the intermediate layer 160 may include a hole injection layer, a hole transport layer, an emission layer, an electron transport layer, and/or an electron injection layer. When the intermediate layer 160 includes a polymer material, the intermediate layer 160 may have a structure generally including a hole transport layer and an emission layer.

The counter electrode 170 may include a light-transmissive conductive layer formed of a light-transmissive conductive oxide, such as ITO, In₂O₃, or IZO. The pixel electrode 150 is used as an anode, and the counter electrode 170 is used as a cathode. The polarity of the electrode may be reversely applied.

The structure of the intermediate layer 160 is not limited to the description presented above, and the intermediate layer 160 may have various structures. For example, at least one of layers forming the intermediate layer 160 may be integrally formed with the counter electrode 170. According to some embodiments, the intermediate layer 160 may include a layer patterned to correspond to each of the pixel electrodes 150.

The counter electrode 170 may be arranged above the display area DA and may be located over the entire surface of the display area DA. In other words, the counter electrode 170 may be integrally formed to cover a plurality of pixels PX. The counter electrode 170 may electrically contact a common power supply line arranged in the peripheral area PA. According to some embodiments, the counter electrode 170 may extend to a blocking wall 200. A thin film encapsulation layer TFE may entirely cover the display area DA and extend toward the peripheral area PA to cover at least a part of the peripheral area PA.

The thin film encapsulation layer TFE may extend to the outside of the common power supply line. The thin film encapsulation layer TFE may include a first inorganic encapsulation layer 310, a second inorganic encapsulation layer 330, and an organic encapsulation layer 320 provided therebetween. The first inorganic encapsulation layer 310 and the second inorganic encapsulation layer 330 may each include one or more inorganic materials of an aluminum oxide, a titanium oxide, a tantalum oxide, a hafnium oxide, a zinc oxide, a silicon oxide, a silicon nitride, and a silicon oxynitride.

The first inorganic encapsulation layer 310 and the second inorganic encapsulation layer 330 may each be a single layer or a multilayer including the materials described above. The first inorganic encapsulation layer 310 and the second inorganic encapsulation layer 330 may include the same material or different materials. The thicknesses of the first inorganic encapsulation layer 310 and the second inorganic encapsulation layer 330 may be different from each other. The thickness of the first inorganic encapsulation layer 310 may be greater than the thickness of the second inorganic encapsulation layer 330. Alternatively, the thickness of the second inorganic encapsulation layer 330 may be greater than the thickness of the first inorganic encapsulation layer 310, or the thicknesses of the first inorganic encapsulation layer 310 and the second inorganic encapsulation layer 330 may be identical to each other.

The organic encapsulation layer 320 may include a monomer-based material or a polymer-based material. The polymer-based material may include acrylic resin, epoxy-based resin, polyimide, polyethylene, etc. According to some embodiments, the organic encapsulation layer 320 may include acrylate.

The blocking wall 200 may be located in the peripheral area PA of the substrate 100. According to some embodiments, the blocking wall 200 may include a portion of the first organic insulating layer 104, a portion 230 of the second organic insulating layer 105, a portion 220 of the pixel defining layer 106, and a portion 210 of the spacer 80, but embodiments according to the present disclosure are not limited thereto.

The blocking wall 200 may be arranged to surround the display area DA, and may prevent or reduce instances of the organic encapsulation layer 320 of the thin film encapsulation layer TFE overflowing to the outside of the substrate 100. The organic encapsulation layer 320 may be in contact with an inner surface of the blocking wall 200 facing the display area DA. The organic encapsulation layer 320 being in contact with the inner surface of the blocking wall 200 may be interpreted such that the first inorganic encapsulation layer 310 is located between the organic encapsulation layer 320 and the blocking wall 200 and the organic encapsulation layer 320 is in contact with the first inorganic encapsulation layer 310.

The first inorganic encapsulation layer 310 and the second inorganic encapsulation layer 330 may be arranged on the blocking wall 200 and may extend to an edge side of the substrate 100. However, in some cases, the blocking wall 200 may include a plurality of blocking walls.

An input sensing layer 400 may be located on the pixel electrode 150. In detail, the input sensing layer 400 may be located on the thin film encapsulation layer TFE. The input sensing layer 400 may have a multilayer structure. The input sensing layer 400 may include a sensing electrode, a sensing signal line (trace line) connected to the sensing electrode, and at least one insulating layer. The input sensing layer 400 may sense an external input, for example, by a capacitive method. As described above, the operation of the input sensing layer 400 is not particularly limited, and in some embodiments, the input sensing layer 400 may sense an external input by an electromagnetic induction method or a pressure sensing method.

The input sensing layer 400 may include a first insulating layer 410, an organic insulating layer 420, a second insulating layer 430, and a touch conductive layer MTL. The touch conductive layer MTL may include a first touch conductive layer MTL1 and a second touch conductive layer MTL2.

The first insulating layer 410 may be located directly on the thin film encapsulation layer TFE. The first insulating layer 410 may include an inorganic material or an organic material, and may be provided in a single layer or a multilayer. The organic material may include at least one material selected from the group consisting of acrylic resin, methacrylic resin, polyisoprene, vinyl-based resin, epoxy-based resin, urethane-based resin, cellulose-based resin, and perylene-based resin. The inorganic material may include at least one material selected from the group consisting of SiN_{X}, an aluminum nitride (AlN), a zirconium nitride (ZrN), a titanium nitride (TiN), a hafnium nitride (HfN), a tantalum nitride (TaN), a silicon oxide (SiO_{X}), Al₂O₃, TiO₂, a tin oxide (SnO₂), a cerium oxide (CeO₂), and SiON.

The first insulating layer 410 may prevent or reduce damage to the thin film encapsulation layer TFE, and may serve to block an interference signal that may be generated during driving of the input sensing layer 400.

For example, the first touch conductive layer MTL1 and the second touch conductive layer MTL2 may each have a single layer structure or a stacked multilayer structure. A conductive layer of a single layer structure may include a metal layer or a transparent conductive layer. The metal layer may include Mo, Ag, Ti, Cu, Al, and an alloy thereof. The transparent conductive layer may include a transparent conductive oxide, such as ITO, IZO, a zinc oxide (ZnO), an indium tin zinc oxide (ITZO), etc. In addition, the transparent conductive layer may include a conductive polymer such as a PEDOT, a metal nano wire, graphene, etc.

A conductive layer of a multilayer structure may include a multilayer of metal layers. The multilayer of metal layers may have, for example, a triple layer structure of Ti/Al/Ti. A conductive layer of a multilayer structure may include at least one metal layer and at least one transparent conductive layer.

The first touch conductive layer MTL1 and the second touch conductive layer MTL2 may each include a plurality of patterns. It may be interpreted that the first touch conductive layer MTL1 includes first conductive patterns, and that the second touch conductive layer MTL2 includes second conductive patterns. The first conductive patterns and the second conductive patterns may form a sensing electrode.

The first touch conductive layer MTL1 and the second touch conductive layer MTL2 may be electrically connected to each other through a contact hole. According to some embodiments, the first touch conductive layer MTL1 and the second touch conductive layer MTL2 may have a mesh structure so that light emitted from a display element OLED may pass therethrough. In this state, the first touch conductive layer MTL1 and the second touch conductive layer MTL2 may be arranged not to overlap an emission area.

The organic insulating layer 420 may include an organic material. The organic material may include at least one material selected from the group consisting of acrylic resin, methacrylic resin, polyisoprene, vinyl-based resin, epoxy-based resin, urethane-based resin, cellulose-based resin, and perylene-based resin. The organic insulating layer 420 may further include an inorganic material. The inorganic material may include at least one material selected from the group consisting of SiN_{X}, AlN, ZrN, TiN, HfN, TaN, SiO_{X}, Al₂O₃, TiO₂, SnO₂, CeO₂, and SiON.

The second insulating layer 430 may be located on the second touch conductive layer MTL2. The second insulating layer 430 may have a single layer or multilayer structure. The second insulating layer 430 may include an organic material, an inorganic material, or a composite material. The inorganic material may include at least one material selected from the group consisting of SiN_{X}, AlN, ZrN, TiN, HfN, TaN, SiO_{X}, Al₂O₃, TiO₂, SnO₂, CeO₂, and SiON. The organic material may include at least one material selected from the group consisting of acrylic resin, methacrylic resin, polyisoprene, vinyl-based resin, epoxy-based resin, urethane-based resin, cellulose-based resin, and perylene-based resin. The first insulating layer 410 and the organic insulating layer 420 may entirely cover the display area DA, and may extend toward the peripheral area PA to cover at least a part of the peripheral area PA.

In the following description, the thin film transistor TFT, the second conductive layer 140, the pixel electrode 150, the intermediate layer 160, the counter electrode 170, the thin film encapsulation layer TFE, and the input sensing layer 400, which are arranged in the display area DA of the substrate 100, are referred to as a display portion DPR.

An optical function layer or the like for relatively improving the light extraction efficiency of the display element OLED may be located on the input sensing layer 400.

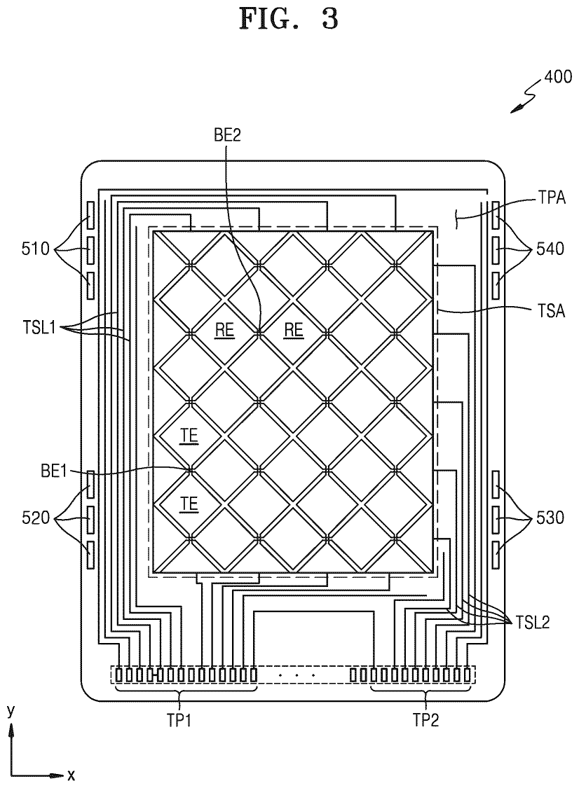

FIG. 3 is a schematic plan view of a portion of the input sensing layer 400 according to some embodiments.

In FIG. 3, illustrated are only a driving electrode TE, a sensing electrode RE, a first sensing signal line TSL1, a second sensing signal line TSL2, a first input sensing pad TP1, a second input sensing pad TP2, and metal patterns 510, 520, 530, and 540, which are included in the first touch conductive layer MTL1 and the second touch conductive layer MTL2 of the input sensing layer 400.

Referring to FIGS. 2 and 3, the input sensing layer 400 may include a touch sensing area TSA for sensing user's touch and a touch peripheral area TPA arranged around the touch sensing area TSA. The touch sensing area TSA may overlap the display area DA of the substrate 100, and the touch peripheral area TPA may overlap the peripheral area PA of the substrate 100.

The driving electrode TE and the sensing electrode RE may each have a planar shape of a rhombus, but embodiments according to the present disclosure are not limited thereto. In FIG. 3, for convenience of illustration, although illustrated as having a planar shape of a rhombus, the driving electrode TE, the sensing electrode RE, a first touch connection electrode BE1, and a second touch connection electrode BE2 may be formed in a mesh structure or a net structure, in a plan view. The sensing electrodes RE may be arranged in a first direction (e.g., x-axis direction) and may be electrically connected to each other. The driving electrodes TE may be arranged in a second direction (e.g., y-axis direction) intersecting the first direction (e.g., x-axis direction) and may be electrically connected to each other. The driving electrodes TE and the sensing electrodes RE may be spaced apart from each other. The driving electrodes TE may be arranged in the second direction (e.g., y-axis direction) parallel to each other. In intersection areas of the sensing electrodes RE and the driving electrodes TE, the driving electrodes TE adjacent to each other in the second direction (e.g., y-axis direction) may be connected to each other through the first touch connection electrode BE1, and the sensing electrodes RE adjacent to each other in the first direction (e.g., x-axis direction) may be connected to each other through the second touch connection electrode BE2.

The first sensing signal line TSL1 and the second sensing signal line TSL2 may be arranged in the touch peripheral area TPA. The driving electrodes TE of the touch sensing area TSA may be connected to the first sensing signal lines TSL1. The first sensing signal lines TSL1 may be connected to the first input sensing pads TP1.

A sensing electrode located at one side end of the sensing electrodes RE may be connected to the second sensing signal line TSL2 and to the second input sensing pads TP2.

Some of the first sensing signal lines TSL1 and the second sensing signal lines TSL2 may be ground wires that are not connected to the driving electrode TE and the sensing electrode RE.

The metal patterns 510, 520, 530, and 540 may be arranged outside the first sensing signal lines TSL1 and the second sensing signal lines TSL2. The metal patterns 510, 520, 530, and 540 may include metal islands apart from the first sensing signal lines TSL1 and the second sensing signal lines TSL2, and may be electrically insulated from other components.

In FIG. 3, a first metal pattern 510 and a fourth metal pattern 540 are arranged in an upper side of the touch peripheral area TPA to face each other with the touch sensing area TSA therebetween, and a second metal pattern 520 and a third metal pattern 530 are arranged in a lower side of the touch peripheral area TPA to face each other with the touch sensing area TSA therebetween, but embodiments according to the present disclosure are not limited thereto. As described above, some of the metal patterns 510, 520, 530, and 540 may be further provided or omitted.

According to some embodiments, the driving electrode TE, the sensing electrode RE, the second touch connection electrode BE2, and the metal patterns 510, 520, 530, and 540 may be provided as the second touch conductive layer MTL2, and the first touch connection electrode BE1 may be provided as the first touch conductive layer MTL1. In other words, the metal patterns 510, 520, 530, and 540 may include the same material as the driving electrode TE, the sensing electrode RE, and the second touch connection electrode BE2. In this state, in the specification, an expression that “A and B include the same material” means that “A and B are formed together through the same process.”

According to some embodiments, the driving electrode TE, the sensing electrode RE, and the second touch connection electrode BE2 may be provided as the first touch conductive layer MTL1, and the first touch connection electrode BE1 and the metal patterns 510, 520, 530, and 540 may be provided as the second touch conductive layer MTL2. In other words, the metal patterns 510, 520, 530, and 540 may include the same material as the first touch connection electrode BE1.

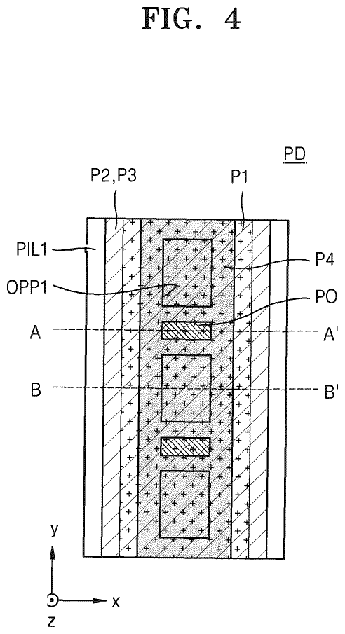

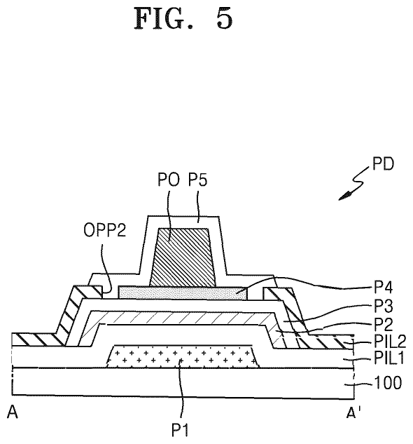

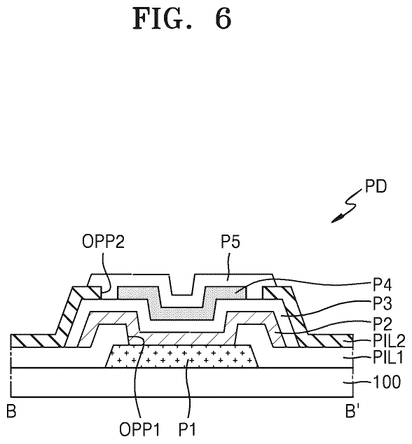

FIG. 4 is a schematic plan view of a pad PD according to some embodiments. FIG. 5 is a schematic cross-sectional view of the pad D taken along the line A-A′ of FIG. 4, according to some embodiments. FIG. 6 is a schematic cross-sectional view of the pad D taken along the line B-B′ of FIG. 4, according to some embodiments.

FIGS. 4 to 6 may be applied to all of the pads PD of FIG. 1 or at least some of the pads PD of FIG. 1.

For convenience of explanation, in FIG. 4, an upper pad layer P5 and a second pad insulating layer PIL2 are not illustrated.

Referring to FIGS. 4 to 6, the pad PD may include a first conductive pad layer P1, a first pad insulating layer PIL1, a second conductive pad layer P2, a third conductive pad layer P3, the second pad insulating layer PIL2, a support pad layer P4, and the upper pad layer P5.

The first conductive pad layer P1 may be located on the substrate 100. The first conductive pad layer P1, as the lowermost layer of the pad PD, may include a conductive material. The first conductive pad layer P1 may form the shape of the pad PD in a plan view of FIG. 4.

The first conductive pad layer P1 may be arranged on the same layer as the gate layer 120 (see FIG. 2) and may include the same material. The first conductive pad layer P1 may have the same layer structure as the gate layer 120. The first conductive pad layer P1 may be formed in the same process as the gate layer 120. The first conductive pad layer P1 may be provided as one body.

The first pad insulating layer PIL1 may be located on the first conductive pad layer P1. The first pad insulating layer PIL1 may cover the first conductive pad layer P1. The first pad insulating layer PIL1 may be arranged on the same layer as the interlayer insulating film 103 (see FIG. 2), and may include the same material as the interlayer insulating film 103 (see FIG. 2). The first pad insulating layer PIL1 may include the same layer structure as the interlayer insulating film 103 (see FIG. 2). The first pad insulating layer PIL1 may be formed in the same process as the interlayer insulating film 103 (see FIG. 2).

The first pad insulating layer PIL1 may include a first pad opening OPP1. The first pad opening OPP1 may include a plurality of first pad openings. The first pad openings OPP1 may be spaced apart from each other in the second direction (e.g., y-axis direction). The first pad opening OPP1 may overlap the first conductive pad layer P1. The first pad opening OPP1 may expose at least a part of the first conductive pad layer P1.

The second conductive pad layer P2 may be located on the first pad insulating layer PIL1, and the second conductive pad layer P2 may be arranged on the same layer and may include the same material as the first conductive layer 130 (see FIG. 2). The second conductive pad layer P2 may have the same layer structure as the first conductive layer 130 (see FIG. 2). The second conductive pad layer P2 may be formed in the same process as the first conductive layer 130 (see FIG. 2). The second conductive pad layer P2 may be provided integrally as one body.

The second conductive pad layer P2 may be electrically connected to the first conductive pad layer P1. The second conductive pad layer P2 may overlap, in a plan view, the first conductive pad layer P1. The second conductive pad layer P2 may be in contact with the first conductive pad layer P1 through the first pad opening OPP1 of the first pad insulating layer PIL1.

The third conductive pad layer P3 may be located on the second conductive pad layer P2, and the third conductive pad layer P3 may be arranged on the same layer and may include the same material as the second conductive layer 140 (see FIG. 2). The third conductive pad layer P3 may have the same layer structure as the second conductive layer 140 (see FIG. 2). The third conductive pad layer P3 may be formed in the same process as the second conductive layer 140 (see FIG. 2). The third conductive pad layer P3 may be provided integrally as one body.

The third conductive pad layer P3 may be electrically connected to the second conductive pad layer P2. The third conductive pad layer P3 may overlap, in a plan view, the second conductive pad layer P2. The third conductive pad layer P3 may be in contact with the second conductive pad layer P2.

The second pad insulating layer PIL2 may be located on the first pad insulating layer PIL1. The second pad insulating layer PIL2 may be located on the third conductive pad layer P3 and may cover the third conductive pad layer P3. In detail, the second pad insulating layer PIL2 may cover at least a part of the third conductive pad layer P3. The second pad insulating layer PIL2 may cover a side surface portion and at least a part of an upper surface of the third conductive pad layer P3.

The second pad insulating layer PIL2 may be arranged on the same layer as the organic insulating layer 420 (see FIG. 2) and may include the same material as the organic insulating layer 420 (see FIG. 2). The second pad insulating layer PIL2 may have the same layer structure as the organic insulating layer 420 (see FIG. 2). The second pad insulating layer PIL2 may be formed in the same process as the organic insulating layer 420 (see FIG. 2).

The second pad insulating layer PIL2 may include a second pad opening OPP2. The second pad opening OPP2 may overlap the third conductive pad layer P3. The second pad opening OPP2 may expose at least a part of the third conductive pad layer P3.

The support pad layer P4 may be located on the substrate 100. In detail, the support pad layer P4 may be located on the third conductive pad layer P3. The first conductive pad layer P1 may be provided between the substrate 100 and the support pad layer P4. The second conductive pad layer P2 may be provided between the first conductive pad layer P1 and the support pad layer P4. The third conductive pad layer P3 may be provided between the second conductive pad layer P2 and the support pad layer P4.

The support pad layer P4 may be arranged on the same layer and may include the same material as the pixel electrode 150 (see FIG. 2). The support pad layer P4 may have the same layer structure as the pixel electrode 150 (see FIG. 2). The support pad layer P4 may be formed in the same process as the pixel electrode 150 (see FIG. 2). The support pad layer P4 may be provided integrally as one body.

The support pad layer P4 may be electrically connected to the third conductive pad layer P3. The support pad layer P4 may overlap, in a plan view, the third conductive pad layer P3 may overlap. The support pad layer P4 may be in contact with the third conductive pad layer P3. At least a part of the support pad layer P4 may be accommodated in the second pad opening OPP2 of the second pad insulating layer PIL2. The support pad layer P4 may be spaced apart from the second pad insulating layer PIL2.

A polymer pad PO may be located on the support pad layer P4. The polymer pad PO may overlap, in a plan view, the support pad layer P4. The support pad layer P4 may support the polymer pad PO. The polymer pad PO may form a protrusion, and the polymer pad PO may protrude in a direction (e.g., z-axis direction) away from the substrate 100.

The polymer pad PO may include a polymer-based material. For example, the polymer-based material may include acrylic resin, epoxy-based resin, polyimide, polyethylene, etc.

A material forming the polymer pad PO may be an insulating material, and may not be a metal material that is a conductive material. The polymer pad PO may have different properties from a wire or an electrode. An electrical signal may be transmitted as not the polymer pad PO, but the upper pad layer P5 described below is in direct contact with the signal pad SPD (see FIG. 1).

The polymer pad PO may include a plurality of polymer pads. The polymer pads PO may be spaced apart from each other in the second direction (e.g., y-axis direction). In a plan view, the polymer pads PO may each be arranged between the first pad openings OPP1.

The upper pad layer P5 may be located on the polymer pad PO. The upper pad layer P5 may cover an upper surface and a side surface of the polymer pad PO. The upper pad layer P5 may cover an upper surface of the support pad layer P4 that is not covered by the polymer pad PO. The upper pad layer P5 may cover an upper surface of the third conductive pad layer P3 that is not covered by the support pad layer P4 and the second pad insulating layer PIL2.

The upper pad layer P5 may be arranged on the same layer and may include the same material as the touch conductive layer MTL (see FIG. 2). The upper pad layer P5 may have the same layer structure as the touch conductive layer MTL (see FIG. 2). The upper pad layer P5 may be formed in the same process as the touch conductive layer MTL (see FIG. 2). The upper pad layer P5 may be provided integrally as one body.

In detail, the upper pad layer P5 may be arranged on the same layer and may include the same material as the second touch conductive layer MTL2 (see FIG. 2). The upper pad layer P5 may have the same layer structure as the second touch conductive layer MTL2 (see FIG. 2). The upper pad layer P5 may be formed in the same process as the second touch conductive layer MTL2 (see FIG. 2).

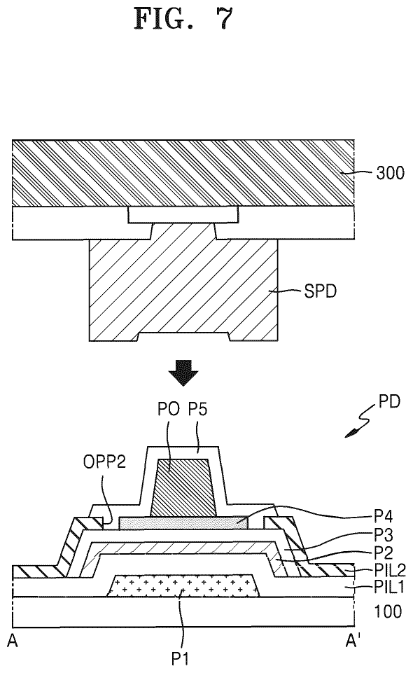

FIG. 7 is a schematic cross-sectional view of the pad PD and the signal pad SPD according to some embodiments.

In FIG. 7, like reference numerals in FIGS. 1 and 5 denote like elements, and some redundant descriptions thereof may be omitted.

Referring to FIG. 7, the pad PD may protrude upward by the polymer pad PO, and the signal pad SPD protruding downward and the pad PD protruding upward may be in direct contact with each other. A lower surface of the signal pad SPD may be formed to be concave corresponding to the protruding shape of the pad PD. The concave shape of the lower surface of the signal pad SPD may correspond to the protruding shape of the upper surface of the pad PD, and thus, the signal pad SPD and the pad PD may be in contact with each other accurately at a desired position.

Referring to FIGS. 4 to 7, one conductive pad layer of the pad PD may be located on the polymer pad PO. In other words, only the upper pad layer P5 of the pad PD may be located on the polymer pad PO. Accordingly, the area of the upper pad layer P5 that is in contact with the signal pad SPD may be reduced. Accordingly, the area of the concave portion formed in the signal pad SPD may also be reduced. Accordingly, the size of the pad PD may be reduced. Furthermore, the pad PD and the signal pad SPD may be in contact with each other accurately at a desired position.

The support pad layer P4 may have higher hardness than each of the first conductive pad layer P1, the second conductive pad layer P2, and the third conductive pad layer P3. Furthermore, the support pad layer P4 may have a greater width than the polymer pad PO. As the support pad layer P4 supports the polymer pad PO, in a process of pressing the pad PD and the signal pad SPD to closely contact each other, the deformation of the first conductive pad layer P1, the second conductive pad layer P2 and the third conductive pad layer P3, which are arranged below the polymer pad PO, may be reduced. Accordingly, the pad PD and the signal pad SPD may be in contact with each other accurately at a desired position.

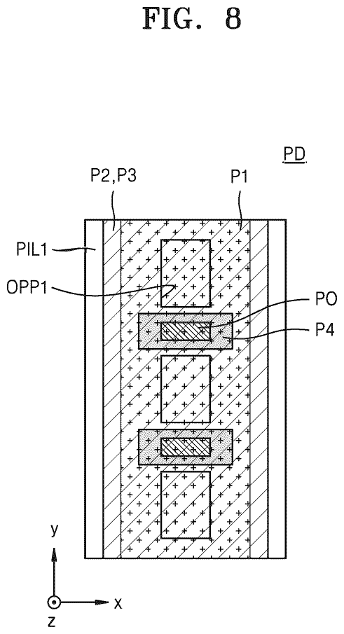

FIG. 8 is a schematic plan view of an example of the pad PD according to some embodiments.

In FIG. 8, like reference numerals in FIG. 4 denote like elements, and some redundant descriptions thereof may be omitted.

Referring to FIG. 8, the polymer pad PO and the support pad layer P4 may include a plurality of polymer pads and a plurality of support pad layers, respectively.

The polymer pads PO may be spaced apart from each other in the second direction (e.g., y-axis direction). The support pad layers P4 may be spaced apart from each other in the second direction (e.g., y-axis direction). In a plan view, each of the support pad layers P4 may overlap a corresponding one of the polymer pads PO. In other words, one the support pad layer P4 may overlap one polymer pad PO. In a plan view, the support pad layers P4 may each be arranged between the first pad openings OPP1.

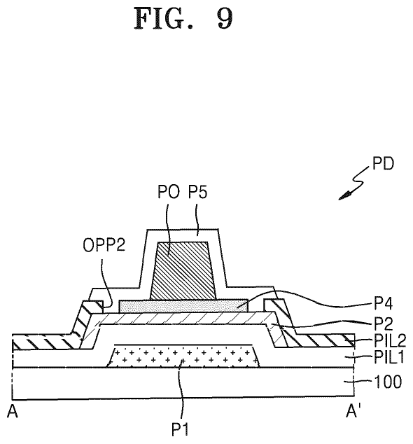

FIG. 9 is a schematic cross-sectional view of the pad PD taken along the line A-A′ of FIG. 4, according to some embodiments.

In FIG. 9, like reference numerals in FIG. 5 denote like elements, and some redundant descriptions thereof may be omitted.

Referring to FIG. 9, the pad PD may include the first conductive pad layer P1, the first pad insulating layer PIL1, the second conductive pad layer P2, the second pad insulating layer PIL2, the support pad layer P4, and the upper pad layer P5. In other words, the pad PD may not include the third conductive pad layer P3 described with reference to FIG. 5.

The first conductive pad layer P1 may be located on the substrate 100. The first conductive pad layer P1 may include the same material as the gate layer 120 (see FIG. 2).

The first pad insulating layer PIL1 may be located on the first conductive pad layer P1. The first pad insulating layer PIL1 may include the same material as the interlayer insulating film 103 (see FIG. 2).

The second conductive pad layer P2 may be located on the first pad insulating layer PIL1. The second conductive pad layer P2 may include the same material as the first conductive layer 130 (see FIG. 2). The second conductive pad layer P2 may be in contact with the first conductive pad layer P1 through the first pad opening OPP1 (see FIG. 4) of the first pad insulating layer PIL1.

The second pad insulating layer PIL2 may be located on the first pad insulating layer PIL1. The second pad insulating layer PIL2 may be located on the second conductive pad layer P2 and may cover the second conductive pad layer P2. The second pad insulating layer PIL2 may include the same material as the organic insulating layer 420 (see FIG. 2).

The second pad insulating layer PIL2 may include the second pad opening OPP2. The second pad opening OPP2 may overlap the second conductive pad layer P2. The second pad opening OPP2 may expose at least a part of the second conductive pad layer P2.

The support pad layer P4 may be located on the second conductive pad layer P2. The first conductive pad layer P1 may be provided between the substrate 100 and the support pad layer P4. The second conductive pad layer P2 may be provided between the first conductive pad layer P1 and the support pad layer P4. The support pad layer P4 may include the same material as the pixel electrode 150 (see FIG. 2).

The support pad layer P4 may be electrically connected to the second conductive pad layer P2. The support pad layer P4 may overlap, in a plan view, the second conductive pad layer P2. The support pad layer P4 may be in contact with the second conductive pad layer P2. At least a part of the support pad layer P4 may be accommodated in the second pad opening OPP2 of the second pad insulating layer PIL2. The support pad layer P4 may be spaced apart from the second pad insulating layer PIL2.

The polymer pad PO may be located on the support pad layer P4. In a plan view, the polymer pad PO may overlap the support pad layer P4. The support pad layer P4 may support the polymer pad PO. The polymer pad PO may form a protrusion, and the polymer pad PO may protrude in the direction (e.g., z-axis direction) away from the substrate 100.

The upper pad layer P5 may be located on the polymer pad PO. The upper pad layer P5 may cover the upper surface and the side surface of the polymer pad PO. The upper pad layer P5 may cover the upper surface of the support pad layer P4 that is not covered by the polymer pad PO. The upper pad layer P5 may cover the upper surface of the second conductive pad layer P2 that is not covered by the support pad layer P4 and the second pad insulating layer PIL2. The upper pad layer P5 may include the same material as the touch conductive layer MTL (see FIG. 2). In detail, the upper pad layer P5 may include the same material as the second touch conductive layer MTL2 (see FIG. 2).

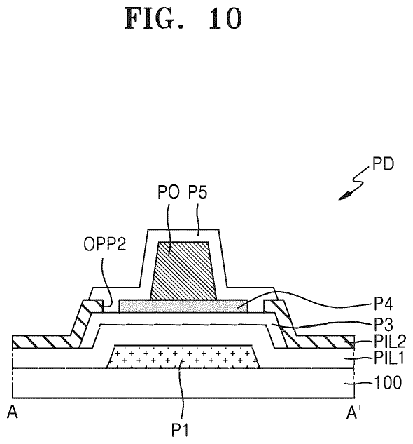

FIG. 10 is a schematic cross-sectional view of the pad PD taken along the line A-A′ of FIG. 4, according to some embodiments.

In FIG. 10, like reference numerals in FIG. 5 denote like elements, and some redundant descriptions thereof may be omitted.

Referring to FIG. 10, the pad PD may include the first conductive pad layer P1, the first pad insulating layer PIL1, the third conductive pad layer P3, the second pad insulating layer PIL2, the support pad layer P4, and the upper pad layer P5. In other words, the pad PD may not include the second conductive pad layer P2 described with reference to FIG. 5.

The first conductive pad layer P1 may be located on the substrate 100. The first conductive pad layer P1 may include the same material as the gate layer 120 (see FIG. 2).

The first pad insulating layer PIL1 may be located on the first conductive pad layer P1. The first pad insulating layer PIL1 may include the same material as the interlayer insulating film 103 (see FIG. 2).

The third conductive pad layer P3 may be located on the first pad insulating layer PIL1. The third conductive pad layer P3 may include the same material as the second conductive layer 140 (see FIG. 2). The third conductive pad layer P3 may be in contact with the first conductive pad layer P1 through the first pad opening OPP1 (see FIG. 4) of the first pad insulating layer PIL1.

The second pad insulating layer PIL2 may be located on the first pad insulating layer PIL1. The second pad insulating layer PIL2 may be located on the third conductive pad layer P3 and may cover the third conductive pad layer P3. The second pad insulating layer PIL2 may include the same material as the organic insulating layer 420 (see FIG. 2).

The second pad insulating layer PIL2 may include the second pad opening OPP2. The second pad opening OPP2 may overlap the third conductive pad layer P3. The second pad opening OPP2 may expose at least a part of the third conductive pad layer P3.

The support pad layer P4 may be located on the third conductive pad layer P3. The first conductive pad layer P1 may be provided between the substrate 100 and the support pad layer P4. The third conductive pad layer P3 may be provided between the first conductive pad layer P1 and the support pad layer P4. The support pad layer P4 may include the same material as the pixel electrode 150 (see FIG. 2).

The support pad layer P4 may be electrically connected to the third conductive pad layer P3. The support pad layer P4 may overlap, in a plan view, the third conductive pad layer P3. The support pad layer P4 may be in contact with the third conductive pad layer P3. At least a part of the support pad layer P4 may be accommodated in the second pad opening OPP2 of the second pad insulating layer PIL2. The support pad layer P4 may be spaced apart from the second pad insulating layer PIL2.

The polymer pad PO may be located on the support pad layer P4. In a plan view, the polymer pad PO may overlap the support pad layer P4. The support pad layer P4 may support the polymer pad PO. The polymer pad PO may form a protrusion, and the polymer pad PO may protrude in the direction (e.g., z-axis direction) away from the substrate 100.

The upper pad layer P5 may be located on the polymer pad PO. The upper pad layer P5 may cover the upper surface and the side surface of the polymer pad PO. The upper pad layer P5 may cover the upper surface of the support pad layer P4 that is not covered by the polymer pad PO. The upper pad layer P5 may cover the upper surface of the third conductive pad layer P3 that is not covered by the support pad layer P4 and the second pad insulating layer PIL2. The upper pad layer P5 may include the same material as the touch conductive layer MTL (see FIG. 2). In detail, the upper pad layer P5 may include the same material as the second touch conductive layer MTL2 (see FIG. 2).

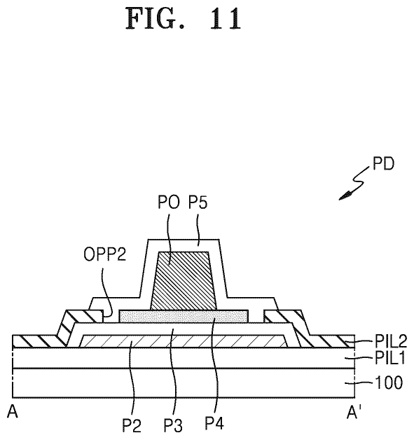

FIG. 11 is a schematic cross-sectional view of the pad PD taken along the line A-A′ of FIG. 4, according to some embodiments.

In FIG. 11, like reference numerals in FIG. 5 denote like elements, and some redundant descriptions thereof may be omitted.

Referring to FIG. 11, the pad PD may include the first pad insulating layer PIL1, the second conductive pad layer P2, the third conductive pad layer P3, the second pad insulating layer PIL2, the support pad layer P4, and the upper pad layer P5. In other words, the pad PD may not include the first conductive pad layer P1 described with reference to FIG. 5.

The first pad insulating layer PIL1 may be the lowermost layer of the pad PD. The first pad insulating layer PIL1 may be located on the substrate 100. The first pad insulating layer PIL1 may cover the substrate 100. The first pad insulating layer PIL1 may include the same material as the interlayer insulating film 103 (see FIG. 2).

The second conductive pad layer P2 may be located on the first pad insulating layer PIL1. The second conductive pad layer P2 may include the same material as the first conductive layer 130 (see FIG. 2). The second conductive pad layer P2 may be electrically connected to the gate layer 120 (see FIG. 2). According to some embodiments, the second conductive pad layer P2 may be in contact with the gate layer 120 (see FIG. 2) through a contact hole formed in the first pad insulating layer PIL1 and/or the interlayer insulating film 103 (see FIG. 2).

The third conductive pad layer P3 may be located on the second conductive pad layer P2. The third conductive pad layer P3 may include the same material as the second conductive layer 140 (see FIG. 2). The third conductive pad layer P3 may be electrically connected to the second conductive pad layer P2.

The second pad insulating layer PIL2 may be located on the first pad insulating layer PIL1. The second pad insulating layer PIL2 may be located on the third conductive pad layer P3 and may cover the third conductive pad layer P3. The second pad insulating layer PIL2 may include the same material as the organic insulating layer 420 (see FIG. 2). The second pad insulating layer PIL2 may include the second pad opening OPP2.

The support pad layer P4 may be located on the third conductive pad layer P3. The support pad layer P4 may include the same material as the pixel electrode 150 (see FIG. 2). The support pad layer P4 may be electrically connected to the third conductive pad layer P3. At least a part of the support pad layer P4 may be accommodated in the second pad opening OPP2 of the second pad insulating layer PIL2. The polymer pad PO may be located on the support pad layer P4. The upper pad layer P5 may be located on the polymer pad PO. The upper pad layer P5 may include the same material as the touch conductive layer MTL (see FIG. 2). In detail, the upper pad layer P5 may include the same material as the second touch conductive layer MTL2 (see FIG. 2).

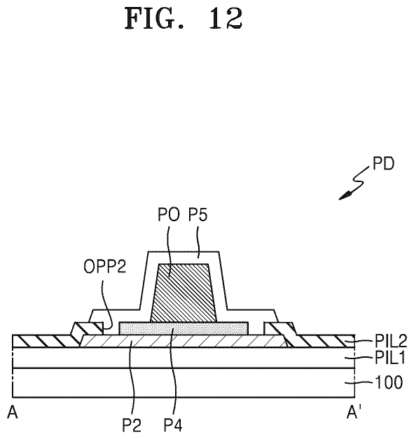

FIG. 12 is a schematic cross-sectional view of the pad PD taken along the line A-A′ of FIG. 4, according to some embodiments.

In FIG. 12, like reference numerals in FIG. 5 denote like elements, and some redundant descriptions thereof may be omitted.

Referring to FIG. 12, the pad PD may include the first pad insulating layer PIL1, the second conductive pad layer P2, the second pad insulating layer PIL2, the support pad layer P4, and the upper pad layer P5. In other words, the pad PD may not include the first conductive pad layer P1 and the third conductive pad layer P3 described with reference to FIG. 5.

The first pad insulating layer PIL1 may be the lowermost layer of the pad PD. The first pad insulating layer PIL1 may be located on the substrate 100. The first pad insulating layer PIL1 may cover the substrate 100. The first pad insulating layer PIL1 may include the same material as the interlayer insulating film 103 (see FIG. 2).

The second conductive pad layer P2 may be located on the first pad insulating layer PIL1. The second conductive pad layer P2 may include the same material as the first conductive layer 130 (see FIG. 2). The second conductive pad layer P2 may be electrically connected to the gate layer 120 (see FIG. 2). According to some embodiments, the second conductive pad layer P2 may be in contact with the gate layer 120 (see FIG. 2) through the contact hole formed in the first pad insulating layer PIL1 and/or the interlayer insulating film 103 (see FIG. 2).

The second pad insulating layer PIL2 may be located on the first pad insulating layer PIL1. The second pad insulating layer PIL2 may be located on the second conductive pad layer P2 and may cover the second conductive pad layer P2. The second pad insulating layer PIL2 may include the same material as the organic insulating layer 420 (see FIG. 2). The second pad insulating layer PIL2 may include the second pad opening OPP2.

The support pad layer P4 may be located on the second conductive pad layer P2. The support pad layer P4 may include the same material as the pixel electrode 150 (see FIG. 2). The support pad layer P4 may be electrically connected to the second conductive pad layer P2. At least a part of the support pad layer P4 may be accommodated in the second pad opening OPP2 of the second pad insulating layer PIL2. The polymer pad PO may be located on the support pad layer P4. The upper pad layer P5 may be located on the polymer pad PO. The upper pad layer P5 may include the same material as the touch conductive layer MTL (see FIG. 2). In detail, the upper pad layer P5 may include the same material as the second touch conductive layer MTL2 (see FIG. 2).

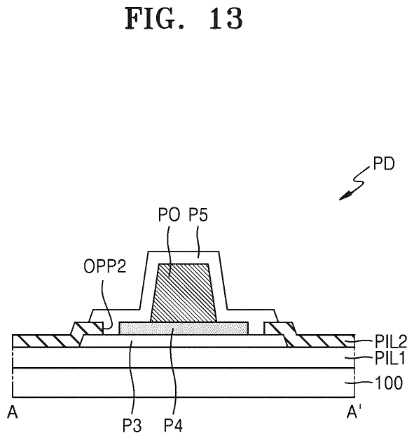

FIG. 13 is a schematic cross-sectional view of the pad PD taken along the line A-A′ of FIG. 4, according to some embodiments.

In FIG. 13, like reference numerals in FIG. 5 denote like elements, and some redundant descriptions thereof may be omitted.

Referring to FIG. 13, the pad PD may include the first pad insulating layer PIL1, the third conductive pad layer P3, the second pad insulating layer PIL2, the support pad layer P4, and the upper pad layer P5. In other words, the pad PD may not include the first conductive pad layer P1 and the second conductive pad layer P2 described with reference to FIG. 5.

The first pad insulating layer PIL1 may be the lowermost layer of the pad PD. The first pad insulating layer PIL1 may be located on the substrate 100. The first pad insulating layer PIL1 may cover the substrate 100. The first pad insulating layer PIL1 may include the same material as the interlayer insulating film 103 (see FIG. 2).

The third conductive pad layer P3 may be located on the first pad insulating layer PIL1. The third conductive pad layer P3 may include the same material as the second conductive layer 140 (see FIG. 2). The third conductive pad layer P3 may be electrically connected to the gate layer 120 (see FIG. 2). According to some embodiments, the third conductive pad layer P3 may be in contact with the gate layer 120 (see FIG. 2) through the contact hole formed in the first pad insulating layer PIL1 and/or the interlayer insulating film 103 (see FIG. 2).

The second pad insulating layer PIL2 may be located on the first pad insulating layer PIL1. The second pad insulating layer PIL2 may be located on the third conductive pad layer P3 and may cover the third conductive pad layer P3. The second pad insulating layer PIL2 may include the same material as the organic insulating layer 420 (see FIG. 2). The second pad insulating layer PIL2 may include the second pad opening OPP2.

The support pad layer P4 may be located on the third conductive pad layer P3. The support pad layer P4 may include the same material as the pixel electrode 150 (see FIG. 2). The support pad layer P4 may be electrically connected to the third conductive pad layer P3. At least a part of the support pad layer P4 may be accommodated in the second pad opening OPP2 of the second pad insulating layer PIL2. The polymer pad PO may be located on the support pad layer P4. The upper pad layer P5 may be located on the polymer pad PO. The upper pad layer P5 may include the same material as the touch conductive layer MTL (see FIG. 2). In detail, the upper pad layer P5 may include the same material as the second touch conductive layer MTL2 (see FIG. 2).

According to some embodiments of the present disclosure, visibility, durability, and quality of a display device may be relatively improved.

The characteristics of embodiments according to the present disclosure are not limited to the above-described characteristics, and other various characteristics that are not described in the specification may be clearly understood from the following descriptions by one skilled in the art to which the present disclosure belongs.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, and their equivalents.

What is claimed is:

1. A display device comprising:
a display panel comprising a substrate including a display area and a pad area, a display portion in the display area of the substrate, and a pad in the pad area of the substrate; and
a connection circuit board comprising a signal pad electrically connected to the pad,
wherein the display portion comprises:
a thin film transistor on the substrate and comprising a semiconductor layer, a gate layer on the semiconductor layer, and a first conductive layer electrically connected to the semiconductor layer;
a second conductive layer on the thin film transistor and electrically connected to the first conductive layer;
a pixel electrode on the second conductive layer to be electrically connected to the second conductive layer; and
an input sensing layer on the pixel electrode and comprising a touch conductive layer and an organic insulating layer, and
wherein the pad comprises:
a support pad layer on the substrate and including a same material as the pixel electrode;
a polymer pad on the support pad layer; and
an upper pad layer on the polymer pad and including a same material as the touch conductive layer.

2. The display device of claim 1, wherein, in a plan view, the polymer pad overlaps the support pad layer, and
the support pad layer supports the polymer pad.

3. The display device of claim 1, wherein the upper pad layer covers the polymer pad.

4. The display device of claim 1, wherein the pad further comprises a first conductive pad layer between the substrate and the support pad layer and includes a same material as the gate layer.

5. The display device of claim 4, wherein the pad further comprises a second conductive pad layer between the first conductive pad layer and the support pad layer, contacts the first conductive pad layer, and includes a same material as the first conductive layer.

6. The display device of claim 5, wherein the pad further comprises a third conductive pad layer between the second conductive pad layer and the support pad layer, contacts the second conductive pad layer, and includes a same material as the second conductive layer.

7. The display device of claim 4, wherein the pad further comprises a third conductive pad layer between the first conductive pad layer and the support pad layer, contacts the first conductive pad layer, and includes a same material as the second conductive layer.

8. The display device of claim 1, wherein the polymer pad and the support pad layer include a plurality of polymer pads and a plurality of support pad layers, respectively, and,
in a plan view, each of the plurality of support pad layers overlaps a corresponding one of the plurality of polymer pads.

9. The display device of claim 8, wherein the plurality of support pad layers are spaced apart from each other.

10. The display device of claim 1, wherein the signal pad contacts the upper pad layer.

11. An electronic device comprising a display panel and a connection circuit board electrically connected to the display panel,
wherein the display panel comprises:
a substrate including a display area and a pad area;
a thin film transistor in the display area of the substrate and comprising a semiconductor layer, a gate layer on the semiconductor layer, and a first conductive layer electrically connected to the semiconductor layer;
a second conductive layer on the thin film transistor and electrically connected to the first conductive layer;
a pixel electrode on the second conductive layer to be electrically connected to the second conductive layer;
an input sensing layer on the pixel electrode and comprising a touch conductive layer and an organic insulating layer;
a support pad layer in the pad area of the substrate and including a same material as the pixel electrode;
a polymer pad on the support pad layer; and
an upper pad layer on the polymer pad and including a same material as the touch conductive layer.

12. The electronic device of claim 11, wherein the connection circuit board comprises a signal pad electrically connected to the upper pad layer.

13. The electronic device of claim 11, wherein, in a plan view, the polymer pad overlaps the support pad layer, and
the support pad layer supports the polymer pad.

14. The electronic device of claim 11, wherein the upper pad layer covers the polymer pad.

15. The electronic device of claim 11, wherein the display panel further comprises a first conductive pad layer between the substrate and the support pad layer and includes a same material as the gate layer.

16. The electronic device of claim 15, wherein the display panel further comprises a second conductive pad layer between the first conductive pad layer and the support pad layer, contacts the first conductive pad layer, and includes a same material as the first conductive layer.

17. The electronic device of claim 16, wherein the display panel further comprises a third conductive pad layer between the second conductive pad layer and the support pad layer, contacts the second conductive pad layer, and includes a same material as the second conductive layer.

18. The electronic device of claim 15, wherein the display panel further comprises a third conductive pad layer between the first conductive pad layer and the support pad layer, contacts the first conductive pad layer, and includes a same material as the second conductive layer.

19. The electronic device of claim 11, wherein the polymer pad and the support pad layer include a plurality of polymer pads and a plurality of support pad layers, respectively, and,
in a plan view, each of the plurality of support pad layers overlaps a corresponding one of the plurality of polymer pads.

20. The electronic device of claim 19, wherein the plurality of support pad layers are spaced apart from each other.
